(19) United States
(12) Patent Application Publication
(10) Pub. No.: US 2002/0167004 A1
(43) Pub. Date: Nov. 14, 2002

(54) Organic molecular film-based electronic switching device utilizing molecular-mechanical motion as the means to change the electronic properties of the molecule

(76) Inventors: Richard H. Henze, San Carlos, CA (US); Patricia A. Beck, Mountain View, CA (US)

Correspondence Address: HEWLETT-PACKARD COMPANY, Intellectual Property Administration, P.O. Box 272400, Fort Collins, CO, 80527-2400, US

(21) Appl. No.: 09/844,851

(22) Filed: Apr. 27, 2001

(51) Int. Cl. H01L 35/24

(52) U.S. Cl. 257/40

(57) ABSTRACT

An electronic switching device is provided that comprises a pair of electrodes and an organic molecular film disposed between the pair of electrodes. The organic molecular film comprises molecules that undergo molecular-mechanical motion between at least two different energetic states. The molecular-mechanical motion comprises any combination of stretching, bending, or torsion of selected bonds, including breaking or making bonds (other than covalent bonds) at specific locations. Changing the electronic properties of the molecule permits its use as a switch, storage element, or logic device.

### TECHNICAL FIELD

The present application is directed to electronic switching devices, and, more particularly, to electronic switching devices based on a variety of molecular switching mechanisms.

### BACKGROUND ART

The prior art for electronic switching and storage devices is primarily characterized by silicon-based, electronic memories of various characteristics, namely:

1. DRAM (dynamic random access memory)—a volatile memory switch configuration that must be electronically refreshed to maintain its state, thereby requiring a continuous power source.

2. SRAM—(static random access memory)—a fast non-volatile memory requiring many devices per memory cell. As a result SRAM tends to be expensive.

3. FLASH MEMORY—a non-volatile memory which has relatively slow writing, reading, and erasing speeds.

4. MRAM (magnetic random access memory)—a non-volatile memory based on a magnetic switching material. MRAM memory cells are switched using magnetic fields generated by currents, and as a result require significant current and power. They have a critical minimum cell size limit below which the magnetic domains will not remain stable.

As logic and storage functions move to smaller and smaller dimensions, emphasis is changing from materials generally used in bulk form, such as semiconductors (e.g., silicon), to an organic molecule-based storage medium. In order for molecules to act in switching logic or storage applications, the molecules must exhibit at least two meta-stable energy states, in which the molecule can reside without being switched to another meta-stable state through thermal energy associated with the environment via a Boltzmann process, but which require the input of some amount of energy to cause the change. The change may be reversible or irreversible.

With regard to organic molecular media and devices employing such for switching logic or storage applications where it is electrically addressed, a relevant reference is published by H. J. Gao et al, “Reversible, Nanometer-Scale Conductance Transitions in an Organic Complex”, Physical Review Letters, Vol. 84, No. 8 (Feb. 21, 2000. U.S. Pat. No. 5,237,067, entitled “Optoelectronic Tautomeric Compositions” and issued on Aug. 17, 1993, to R. R. Schumaker, describes a class of compounds which exhibit intramolecular ring-opening, ring-closing behavior which can be applied to optoelectronic switching devices.

A number of such chemical transformations are known that permit switching from one energetic state to another that involve the opening or closing of rings via breaking or making covalent bonds. Apparently, however, there is little information in the way of molecular-mechanical motions involving the transformation from one meta-stable state to another meta-stable state without breaking or making covalent bonds. Such molecular-mechanical motion is based only on some movement of a part of the molecule relative to another part of the molecule, rather than the making and breaking of chemical covalent bonds. Examples of such molecular-mechanical motion may involve hydrogen bonding, van der Waals forces, and the like.

Thus, there is a need for a “tool box” of molecular configurations, from which the molecular designer may select one or more appropriate mechanical motions for providing classes of molecules useful in switching logic or storage applications.

### DISCLOSURE OF INVENTION

In accordance with the present invention, molecular configurations are provided that can result in molecular-mechanical motion as a means of changing the electronic properties of the molecule so it can be employed as a switch, storage element, or logic device. By incorporating mechanical conformation changes, the molecule may exhibit beneficial properties such as:

1. A bi-stable molecular configuration, where each stable molecular state exhibits a distinct electronic property which may be sensed, such as a difference in electrical conductivity.

2. A sufficient energy barrier to resist a state reversal, which barrier acts as a latch. This barrier will determine the stable lifetime of the molecular state characterized by its ability to resist reversal caused by thermal energy.

3. A means to actuate or re-configure the molecular material from one state to the other, preferably, with the ability to do this repeatedly over a large number of cycles.

4. A suitable margin between half-select and full-select addressing conditions such that when used in a cross-point memory application, states of the molecular switches in the same row or column as the addressed switch will not be changed.

The electronic switching device of the present invention comprises a pair of electrodes and an organic molecular film disposed between the pair of electrodes. The organic molecular film comprises molecules that undergo molecular-mechanical motion resulting in at least two different energetic states. The molecular-mechanical motion comprises any combination of stretching, bending, or torsion of selected bonds, including breaking or making bonds, other than covalent bonds, at specific locations. Examples include employing hydrogen bonding, van der Waals forces, and the like.

Logic and memory applications for electronic switches are wellknown. A molecular-based switch offers the potential for nano-scale memory or logic devices. Devices using organic molecular-based solid-state films as the switching media may be fabricated at a very low cost. The switching and latching mechanisms of a particular molecule will determine the switching characteristics, cycle-ability, and robustness of the switch for a particular application.

A mechanical change in the configuration of a molecule is likely to have a significant impact on the electronic state of the molecule, and therefore on the electronic properties of the molecule. Some molecular compositions could result in a plurality of stable structural configurations, where each configuration results in a different state of the device. In addition, a change in the mechanical configuration can be exploited as a means of increasing the switching force and/or stability of the switch.

### BRIEF DESCRIPTION OF THE DRAWINGS

FIGS. 1-9 depict examples of molecular motion that may form the basis for reversible or irreversible energetic states, wherein:

FIGS. 1a-1c schematically depict folding of a molecular chain (FIG. 1a) to a partially folded state (FIG. 1b) and thence to a fully folded state (FIG. 1c);

FIGS. 2a-2b schematically depict a zipper-like “Y” configuration, alternating between unzipped (FIG. 2a) and zipped (FIG. 2b);

FIGS. 3a-3b schematically depict a hinged, or clamshell, structure in the open position (FIG. 3a) and in the closed position (FIG. 3b);

FIGS. 4a-4b schematically depict a rotating ring and axle configuration, wherein the ring rotates from one position (FIG. 4a) to at least one other position (FIG. 4b);

FIGS. 5a-5d schematically depict a structure similar to that shown in FIGS. 4a-4b, except that the ring tilts on an axle between a first position (FIGS. 5a-5b) and a second position (FIGS. 5c-5d), where FIGS. 5aand 5c depict the plan view of the molecular structure and FIGS. 5b and 5d depict the side view of the molecular structure;

FIGS. 6a-6b schematically depict a coil spring arrangement that can expand (FIG. 6a) and contract (FIG. 6b);

FIGS. 7a-7b schematically depict a cylindrical helix arrangement that can contract (FIG. 7a) and expand (FIG. 7b);

FIGS. 7c-7d schematically depict a conical helix arrangement that can expand (FIG. 7c) and contract (FIG. 7d);

FIGS. 8a-8b schematically depict a linkage-like arrangement that can expand (FIG. 8a) and contract (FIG. 8b), analogous to an accordion; and

FIGS. 9a-9c schematically depict a configuration that can be used individually or in complementary pairs to alter a tunneling junction between two electrodes, in which in FIGS. 9a and 9b, a molecule on one electrode can change between a first configuration in which the molecule is close to that electrode (FIG. 9a) and a second configuration in which the molecule extends toward the second electrode (FIG. 9b), and in which in FIG. 9c, two identical molecules, one on each electrode, can assume the close position (as shown by the dashed lines) or the extended position.

### BEST MODES FOR CARRYING OUT THE INVENTION

The present invention is directed to a molecular configuration that undergoes a change in shape as a result of changing the molecular bond structure, or by the application of electrostatic forces. The change in shape can alter the electronic properties of the molecule via two possible mechanisms. The first mechanism involves reconfiguring the molecular conformation such that electrical conduction through the molecule will be altered. The second mechanism involves molecular motion that changes the dimension between two electrodes or between two parts of the molecule to alter a tunneling junction between electrodes.

A preferred device application for a molecular film exhibiting this behavior is an electronic switch defined by a cross-point arrangement of electrodes in which the molecule(s) present between two opposing electrodes represent(s) the storage media. An alternate device application would be for a probe-addressable storage device where a probe tip is used to configure and sense local regions of the molecular material via electrical or mechanical means.

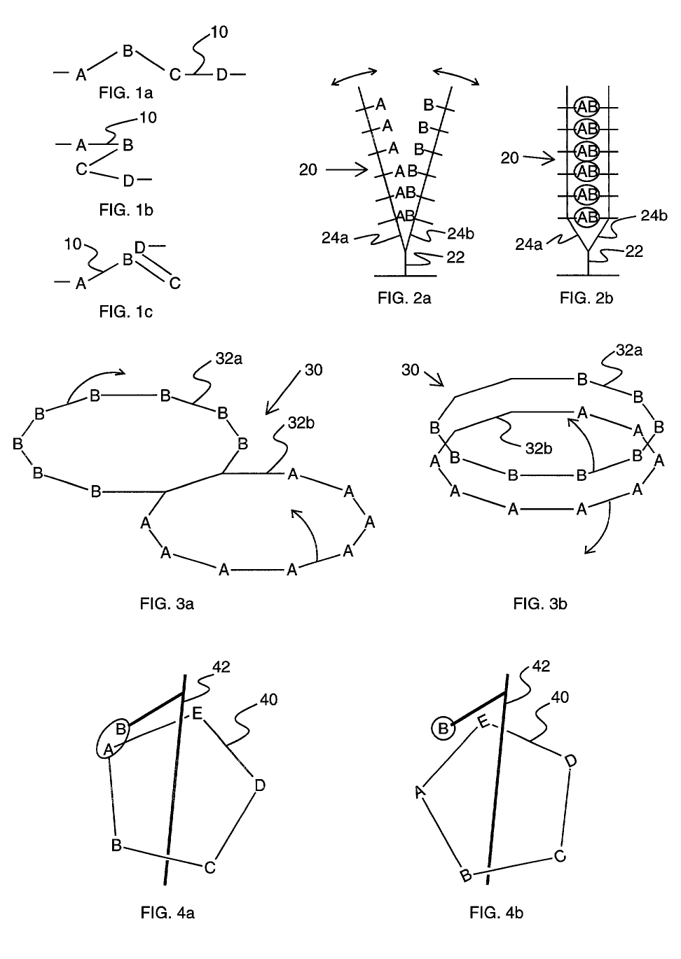

The mechanical motion at the molecular scale is accomplished via stretching, bending, and/or torsion of selected bonds, potentially in combination with breaking or making bonds at specific locations. The molecules may be designed to in-corporate corporate rigid groups that work in conjunction with flexible groups to facilitate a desired behavior. Several shapes and mechanical configurations from the macroscopic world can be translated to the molecular level. Some examples are shown in FIGS. 1-8. In these Figures, the letters are intended to represent functional groups within the molecule that have the propensity for attraction, repulsion, or bonding with other groups; the letters, however, do not represent elements (e.g., “C” does not represent carbon).

FIGS. 1a-1c depict a polymer chain 10 A-B-C-D with one or multiple ways of folding. FIG. 1a depicts the chain 10 in a relatively open position. FIG. 1b depicts the chain 10 in a partially folded position. FIG. 1c depicts the chain 10 in a substantially folded position. Each state is seen to be energetically distinct from the other states. The folding may be assisted, for example, by functional groups on the chain 10 that can form and break bonds. An example of molecular folding is given in a co-pending patent application having Serial No.______, filed ______[PD-10013977-1], entitled “Molecular Mechanical Devices with a Band Gap Change Activated by an Electric Field for Optical Switching Applications” by Xiao-An Zhang et al and assigned to the same assignee as the present application, which is incorporated herein by reference.

FIGS. 2a-2b depict a molecule configured as a “zipper” 20, comprising a base portion 22 and two split lobe portions 24a, 24b, where a correlated action of adjacent sites allows the reversal between a separated “Y” (unzipped) state (FIG. 2a) and a joined “I” (zipped) state (FIG. 2b). In essence, the A groups on lobe 24a bond with the B groups on lobe 24b. The bonding can be via ionic bonding, hydrogen bonding, or other non-covalent bonding, as described more fully below. An example of a molecule that behaves as depicted in FIGS. 2a-2b is DNA.

FIGS. 3a-3b depict a hinged arrangement in which a clamshell-like structure 30, comprising two portions 32a, 32b, is able to open (FIG. 3a) and close (FIG. 3b). Such clamshell structures are known; see, e.g., U.S. Pat. No. 5,154,890, entitled “Fiber Optic Potassium Ion Sensor”, issued Oct. 13, 1992, to G. R. Mauze et al and assigned to the same assignee as the present invention. In this reference, a lyo-philic group linking two 15-crown-5 groups in an ionophore e.g., 2,2-bis[3,4-(15-crown-5)-2-nitrophenylcarboxy-methyl]-tetra-decane, folds such that a hydrogen bond is formed between an oxygen of an NO group near one crown group and a hydrogen of an NH group near the other crown group.

FIGS. 4a-4b depict a ring 40 and axle 42 arrangement, such that the ring can rotate to multiple positions with respect the axle. FIG. 4a depicts the ring 40 in one position with respect to the axle 42, while FIG. 4b depicts the ring in another position with respect to the axle. Refinements to the rotating ring include a ratcheting effect to limit direction of travel to only one direction. An example of rotation of one part of a molecule relative to another part is given in the above-referenced co-pending patent application, in its discussion of rotor-stator portions.

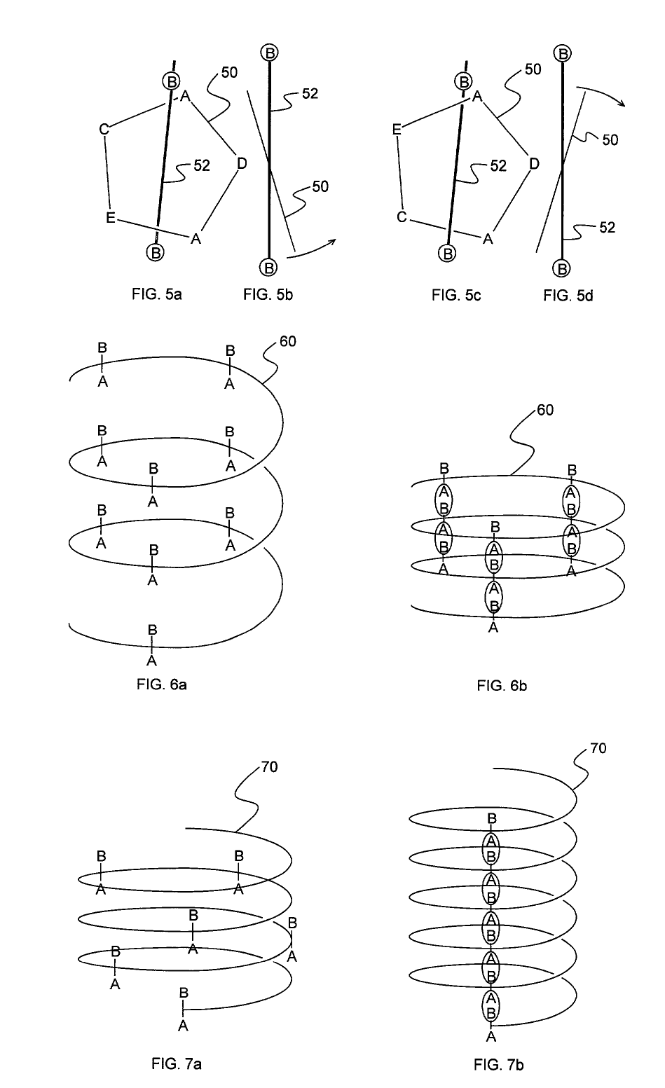

FIGS. 5a-5d depict a similar arrangement as FIGS. 4a-4b, but where the ring 50 pivots on the axle 52 rather than rotates. The moieties labeled “B” are attached to electrodes (not shown), so that only the ring 50 can execute the mechanical motion of pivoting. The pivoting action is seen more clearly in FIGS. 5b and 5d.

FIGS. 6a-6b depict a coil spring arrangement in which a chain 60 can expand (FIG. 6a) and contract (FIG. 6b). As in FIGS. 1a-1b, the chain can include functional groups, here, A and B groups, that can form and break bonds, for example, to assist in the expansion and contraction. An example of expansion and contraction of a coil is the DNA molecule.

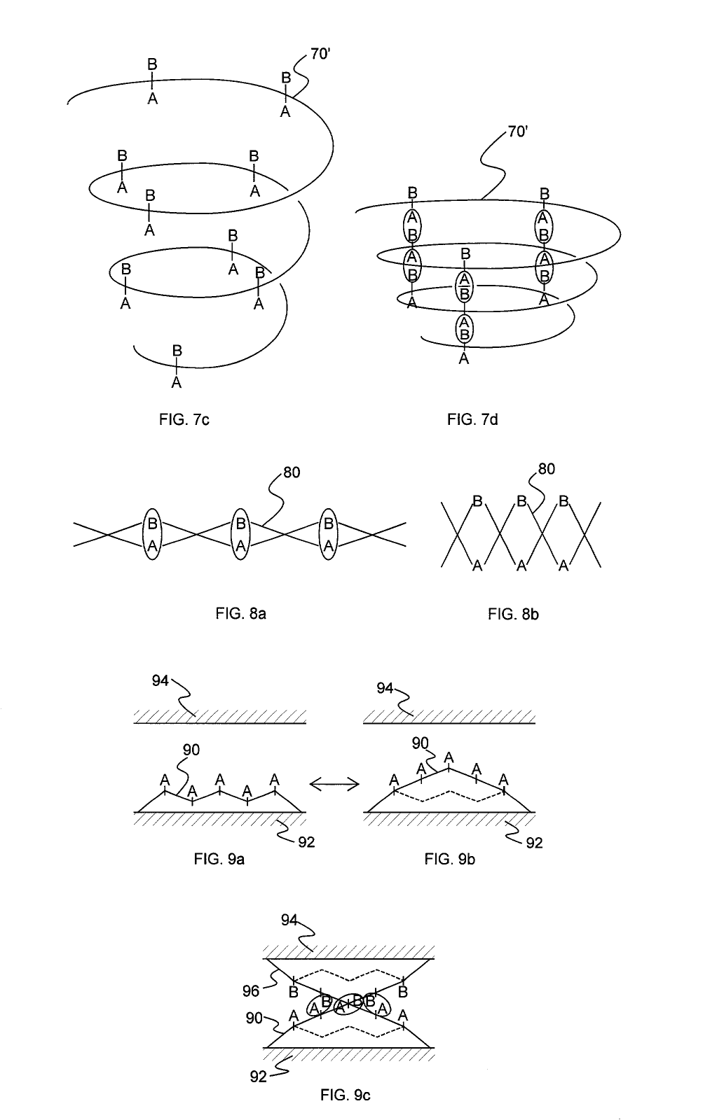

FIGS. 7a-7d depict a screw-like arrangement in which a chain 70, 70′ can expand and contract. FIGS. 7a-7b are directed to the contraction (FIG. 7a) and expansion (FIG. 7b) of a cylindrical helix spring 70. FIGS. 7c-7d are directed to the expansion (FIG. 7c) and contraction (FIG. 7d) of a conical helix spring 70′. As in FIGS. 6a-6b, the chain 70, 70′ can include functional groups, here, A and B groups, that can form and break bonds, for example, to assist in the expansion and contraction.

FIGS. 8a-8b depict a linkage-like arrangement in which a chain 80 can expand (FIG. 8a) and contract (FIG. 8b) like an accordion. As in FIGS. 6a-6b, the chain can include functional groups, here, A and B groups, that can form and break bonds, for example, to assist in the expansion and contraction. A variation of this structure can utilize asymmetric expansion and contraction, such as a folding fan.

FIGS. 9a-9c depict a configuration that can be used individually or in complementary pairs to alter a tunneling junction. In particular, FIGS. 9a and 9b depict a single molecule 90 attached to one of two electrodes 92, 94. The molecule 90 is shown in a contracted position in FIG. 9a and in an expanded position in FIG. 9b, having moved closer to the other electrode 94, thereby permitting tunneling of electrons to occur.

In FIG. 9c, a pair of such molecules 90, 96 is attached to the electrodes 92, 94, one to each electrode. The molecules 90, 96 in the contracted position are shown by the dashed lines. In the expanded position, the molecules 90, 96 extend toward each other, again permitting tunneling of electrons to occur. In this latter case, the molecules can include functional groups, here, A and B groups, that can form and break bonds, for example, to assist in the expansion and contraction.

By chemically bonding hydrophilic and hydrophobic end groups onto opposing ends of these various molecular configurations, Langmuir-Blodgett film techniques can be used to apply the molecular material to a substrate.

In some cases, such as the embodiments depicted in FIGS. 2a-2b, 6a-6b, 7a-7b, and 7c-7d, it may be desirable to secure one end of the chain to a substrate and to permit the respective molecular-mechanical motion to proceed relative to that substrate.

Actuation mechanisms to generate the molecular-mechanical motion include an applied electric field, for example, generated by a voltage difference applied across opposing electrodes. The electric field can act on a dipole moment or spatial charge distribution present in the molecule to locally displace part of the molecule. The electric field can induce a non-uniform charge distribution within a region of the molecule, which then affects Coulomb forces within the molecule.

Another actuation mechanism is the introduction or removal of electrons from a redox-active functional group contained within the molecule to the electrodes, resulting in a localized change within the molecule that imposes electrostatic interactions with other charged regions within the molecule; see, e.g., C. P. Collier et al, “Electronically Configurable Molecular-Based Logic Gates”, Science, Vol. 285, pp. 391-392 (Jul. 16, 1999).

Switch behavior results if the material can be latched to maintain a stable conformation. In principle, any electrostatic forces or chemical bonds established between different parts of the molecule can be used to latch its conformation. This could be accomplished by means of covalent, ionic, or hydrogen bonding at corresponding locations of functional groups. If the energy barrier associated with changing this latched state is a sufficient magnitude, the switch can be suitable for a non-volatile storage application.

Design of the latching mechanism and its energy barrier can play a significant role on the ultimate device application and utility. A relatively large energy barrier required to overcome a latched state will result in long term stability required for non-volatile applications, but will require switching energies that may be difficult to implement in a practical fashion or result in breakdown of the molecular material in other undesired regions. This would be a good design strategy for write-once applications where reversal is not required. Catalytic reactions involving complementary compounds may be a desirable mechanism to selectively lower the energy barrier for the overcoming the latch.

Hydrogen bonding or other electrostatic latching implementations provide a relatively lower energy barrier to reversal, resulting in predictable reversible behavior. This barrier may be so low that the latch may not maintain a suitable lifetime due to thermal energy, resulting in the spontaneous degradation from the latched state. Steric hindrance and/or the use of a plurality of bonding sites to provide ensemble behavior are possible strategies that may be incorporated in the mechanical motion-molecular design strategy to increase the energy barrier required to overcome the latching force, while still allowing robust, reversible switching.

### INDUSTRIAL APPLICABILITY

The organic molecular film-based structures disclosed and claimed herein are expected to find use in electronic switching devices.

What is claimed is:

1. An electronic switching device comprising a pair of electrodes and an organic molecular film disposed between said pair of electrodes, said organic molecular film comprising molecules that undergo molecular-mechanical motion between at least two different energetic states.

2. The electronic switching device of claim 1 wherein said molecular-mechanical motion comprises any combination of stretching, bending, or torsion of selected bonds, including breaking or making bonds at specific locations.

3. The electronic switching device of claim 2 wherein said molecular-mechanical motion comprises folding and unfolding of a molecular chain.

4. The electronic switching device of claim 3 wherein said molecular-mechanical motion comprises folding to a partially folded state.

5. The electronic switching device of claim 3 wherein said molecular-mechanical motion comprises folding to a fully folded state.

6. The electronic switching device of claim 2 wherein said molecular-mechanical motion comprises movement between a zipper-like unzipped “Y” configuration and a zipped “I” configuration.

7. The electronic switching device of claim 2 wherein said molecular-mechanical motion comprises movement along a hinged clamshell structure between an open position and a closed position.

8. The electronic switching device of claim 2 wherein said molecular-mechanical motion comprises rotation of a rotating ring relative to an axle, wherein the ring rotates from one position to at least one other position relative to said axle.

9. The electronic switching device of claim 2 wherein said molecular-mechanical motion comprises tilting of a ring relative to an axle between a first position and a second position.

10. The electronic switching device of claim 2 wherein said molecular-mechanical motion comprises movement of a molecule having a coil spring configuration between an open position and a contracted position.

11. The electronic switching device of claim 2 wherein said molecular-mechanical motion comprises movement of a molecule having a cylindrical helix configuration between an open position and a contracted position.

12. The electronic switching device of claim 2 wherein said molecular-mechanical motion comprises movement of a molecule having a conical helix configuration between an open position and a contracted position.

13. The electronic switching device of claim 2 wherein said molecular-mechanical motion comprises movement of a molecule having a linkage-like configuration between an open position and a contracted position.

14. The electronic switching device of claim 2 wherein said molecular-mechanical motion comprises movement of a molecule having two end portions secured to an electrode toward and away from a second electrode.

15. The electronic switching device of claim 2 wherein said molecular-mechanical motion comprises movement of two molecules, a first molecule having two end portions secured to a first electrode and a second molecule having two end portions secured to a second electrode, wherein said movement comprises movement of said two molecules toward and away from each other.

16. The electronic switching device of claim 1 wherein said device is selected from the group consisting of electronic switches, storage devices, and logic devices.
